(19) United States
(12) Patent Application Publication
(10) Pub. No.: US 2011/0095987 A1
(43) Pub. Date: Apr. 28, 2011

(54) 12-KEY QWERTY TEXT ENTRY METHOD

(76) Inventor: Itsuro Yoshimoto, Sunnyvale, CA (US)

(21) Appl. No.: 12/933,555

(22) PCT Filed: Apr. 1, 2008
(86) PCT No.: PCT/US08/59033

§ 371 Date: Nov. 12, 2010

(30) Foreign Application Priority Data
Mar. 31, 2008 (US) 090000YOSHI100U

(51) Int. Cl. H03M 11/00; G06F 3/02

(52) U.S. Cl. 345/170; 341/22

(57) ABSTRACT

New QWERTY key layout text entry method, which is designed to allow users to achieve high-speed text entry such as alphabet, numbers and symbols, on relatively small-sized devices such as cellular phones, smart phones, IP phones, landline phones, PDAs, watches, remote controllers, game controllers, Karaoke controllers, car navigation controllers, single-hand use assistive PC keyboard and other devices. Three different characters are assigned for each single keypad, and one extra character is assigned to the gap space in between two keypads, comprising manually operated two actuator elements beneath each keypad. Single key press operation at the position of left, right, or middle part of the key-top convert three different states including simultaneous activation of the two actuator elements. Single key press operation at the middle gap space area between two neighboring keypads generate additional unique state, by right side of actuator element of left side keypad and left side of actuator element of right side keypad are simultaneously activated. Three keypads in a same row can generate total 11 unique states by single key press operation.

12-key device such as cellular phone, keys (1,2,3,4,5,6,7,8,9,0,*,#) in three columns by four rows, can adopt Standard QWERTY keyboard's key layout with this invention, such as 1^{st} row[QWERTYUIOP@], 2^{nd} row[ASDFGHJKL;'], 3^{rd} row[ZXCVBNM, ./?], 4^{th} row[SHIFT, SPACE, ENTER], and also double the key entry to cover numbers and all standard symbols on QWERTY keyboard with SHIFT+ key operation.

Furthermore, the existing multiple key press text entry method for standard phone number-alphabet key assignment such as [2abc]method can also achieve by single key press operation without changing key assignment by adopting this invention.

### CROSS-REFERENCES TO RELATED APPLICATIONS

This application claims the benefit of Provisional Application No. 60/629,546, filed Nov. 19, 2004 and is a continuation in part of PCT Application No. PCT/US05/12009, U.S. Ser. No. 11/283,510, U.S. 60/718,107, each of which contains related claims by reference.

### REFERENCES CITED

U.S PATENT DOCUMENTS

| | | | |
|---|---|---|---|
| 5,528,235 A | Edward Lin, | 6,043,761 A | Gregory N. Smallwood |
| | Wallace Lin | | |
| 6,731,227 A | Kenichi Horie | 6,911,970 A | Tai Chun Wen |
| 7,091,885 A | Vadim Fux, etc | 7,096,036 A | Jason Griffin, etc |

### FIELD OF THE INVENTION

This present invention relates to data input device. More specifically, the present method and system includes a key arrangement on a handheld electrical device such as a cellular phone. Merely by way of example, the key arrangement can be applied to a 12-key cellular phone product, but can also be applied to smart phone, IP phone, game consoles' controller, remote controls for home entertainment devices or computing devices, personal digital assistants (PDA), watches, karaoke controllers, car navigation controllers, single-hand use assistive PC keyboard, any combination of these, any 12 key device and the like.

### BACKGROUND OF THE INVENTION

Using cellular phones for data services, such as e-mail, instant messaging and SMS, are becoming more and more popular. Users are accustomed to the conventional cellular phone key arrangement with 12 keys in three columns by four rows. As shown in FIG.-01, alphabets are assigned to each numeric keys from 2 to 9 as a standard format such as 2(ABC), 3(DEF), 4(GHI), 5(JK), 6(MO), 7(PQRS), 8(TUV), 9(WXYZ), and it is recommended to keep this key assignment for a consistency between different phone system. Each key is used primarily to input a single number 0-9 or a function * or #. Some of the keys are also used to input letters A-Z or symbols, requiring often multiple presses of the same key.

Given the size of the keypad, easy, quick and accurate key input of the letters and symbols for data services is a critical issue.

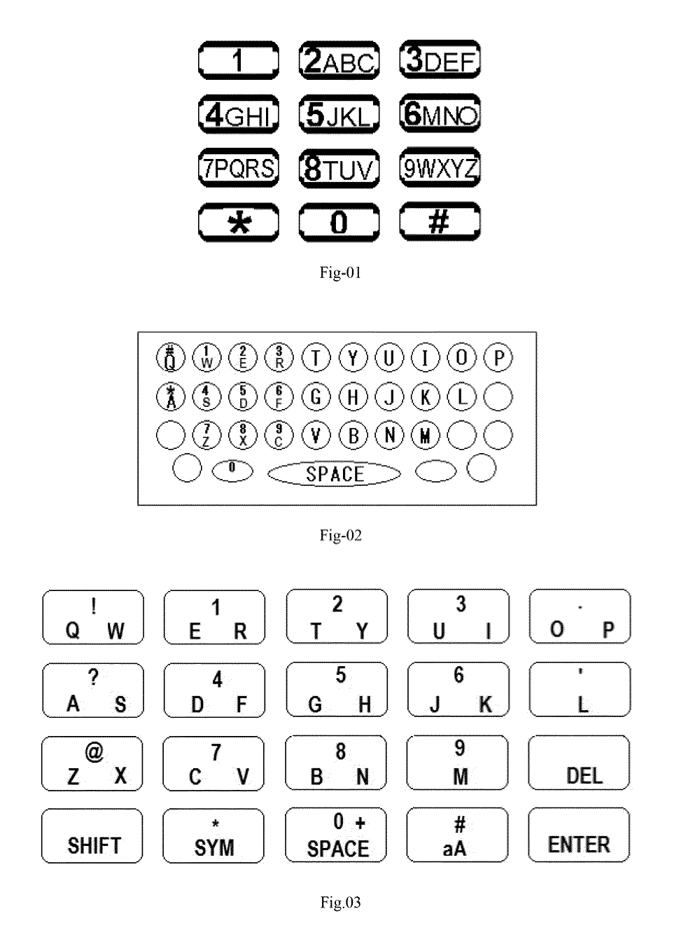

As shown in FIG. 02, Blackberry type device which supports alphabet keys in ten columns by four rows, QWERTY keyboard devices become standard text entry method in smart phone market. Recently, this trend is influencing into cellular phone market where its market size is a hundredfold larger than smart phone.

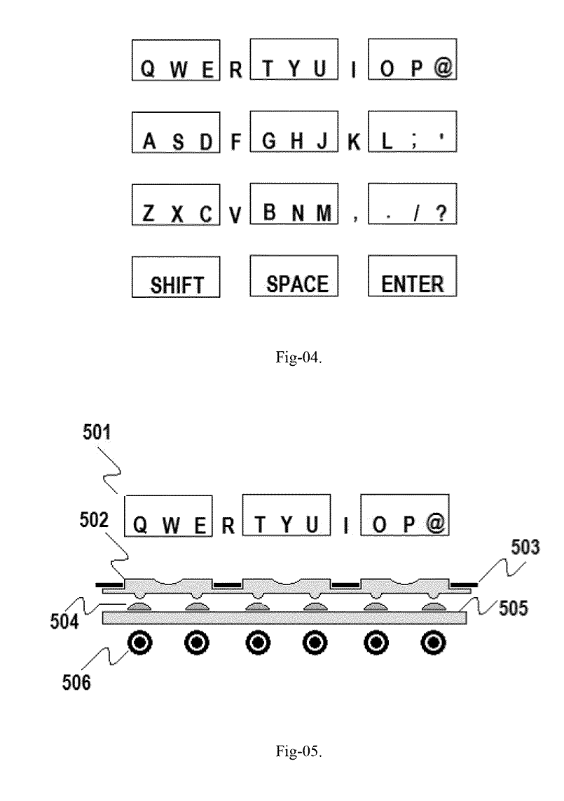

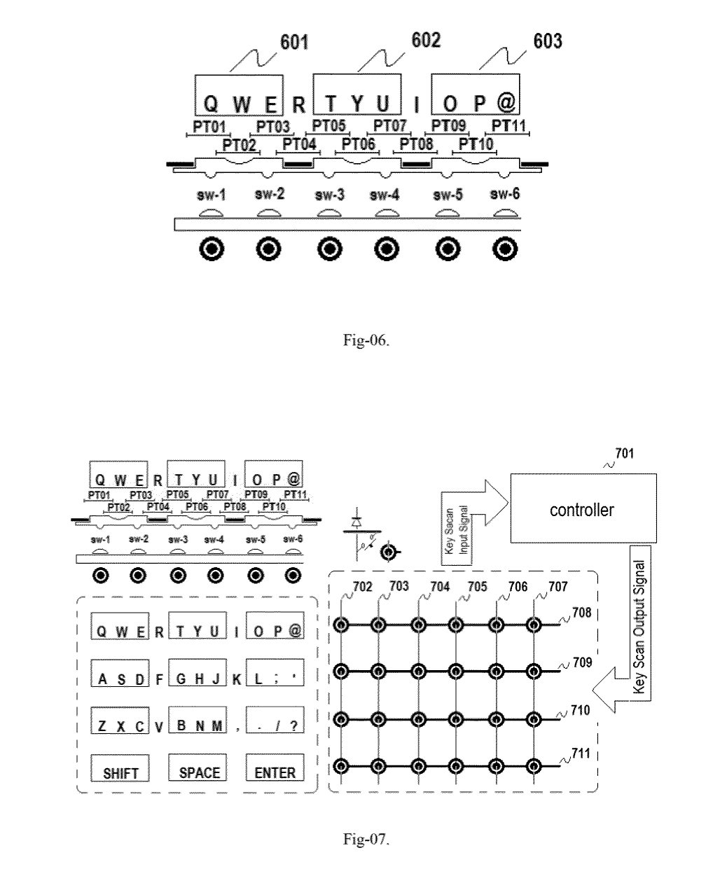

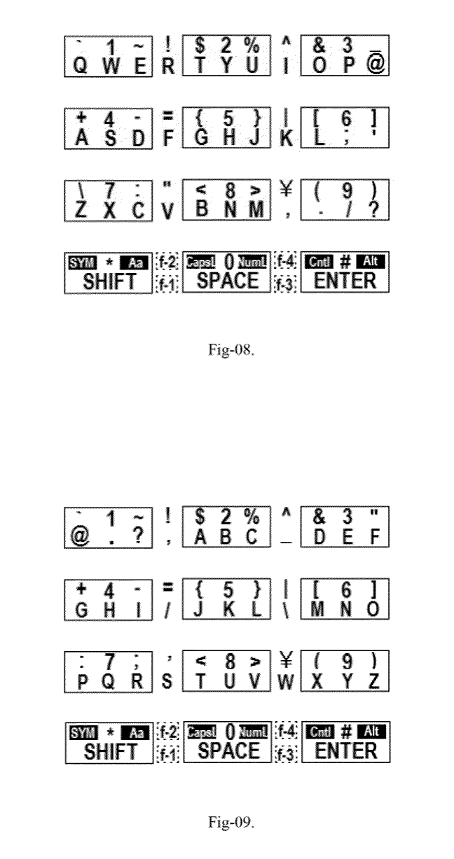

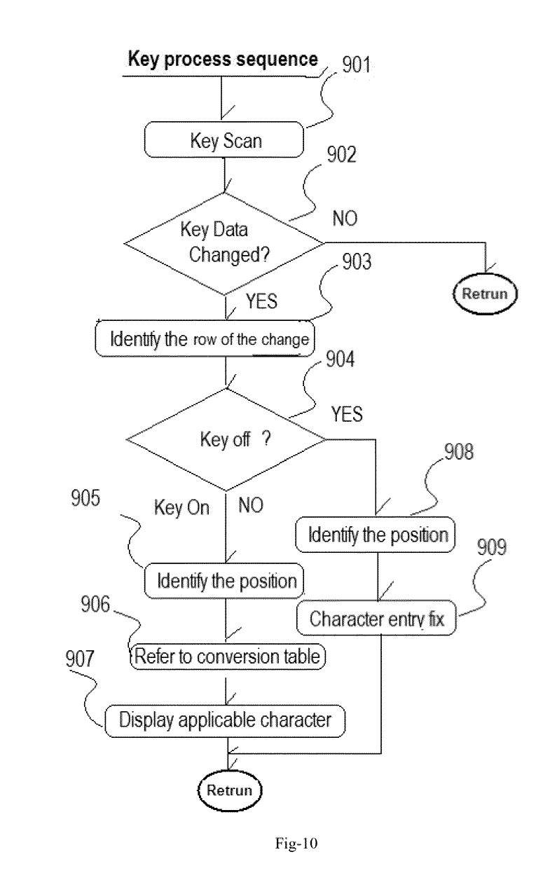

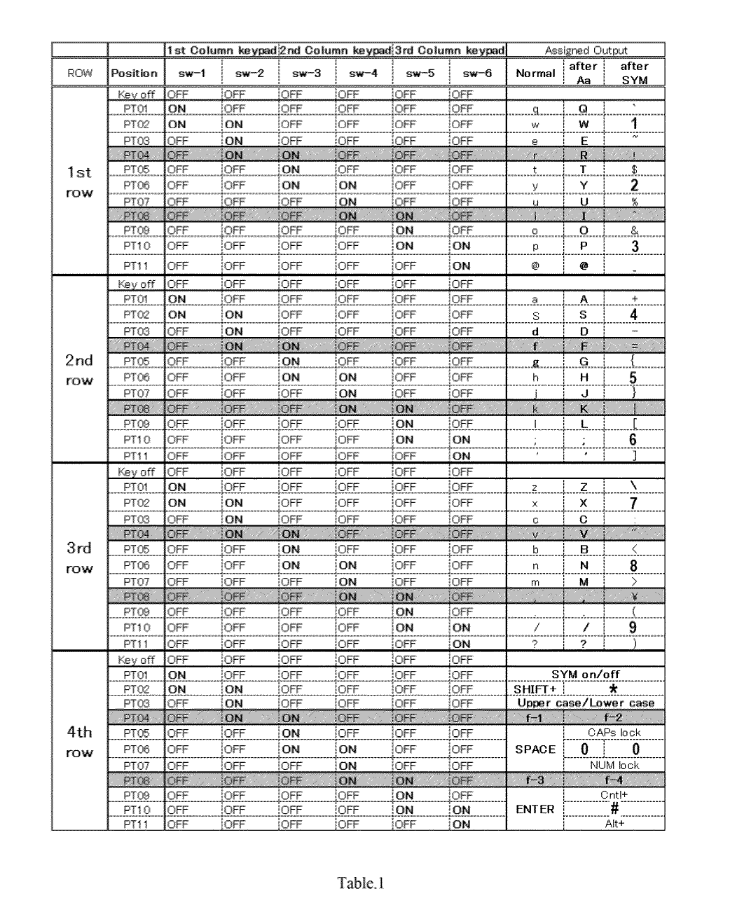

U.S. Pat. No. 7,091,885 discloses QWERTY key arrangement with 20 keys in five columns by four rows. As shown in FIG. 03, two alphabets are assigned to single keypad, and each letter is selected intelligently with predictive method by referring internal dictionary. However, predictive input method cannot achieve accurate letter selection due to limited size of internal dictionary which popular T9 input technology has similar problem.

U.S. Pat. No. 7,096,036 disclose dual-mode keypad include a plurality of dual switches that each include an associated character to solve said U.S. Pat. No. 7,091,885 problem. However, 20 keys in five columns by four rows become a little bit bulky device.

U.S. Pat. Nos. 6,911,970 and 6,931,125 disclose plurality of contacts on the rear face of a keypad key that each mate with an individual contact pad from a plurality of contact pads placed below the upwardly biased and tiltable keys. Pushing a key on a right, middle or left side mates different pairs of contacts which generate three different characters from single keypad. Keypads in three columns by four rows generate maximum 36 different characters by a single key press. However, it is desirable to adapt QWERTY key assignment for users.

U.S. Pat. No. 6,731,227 disclose QWERTY keypad in three columns by four rows include an inclination sensor or an angular velocity sensor for allocating the same arrangement of the QWERTY type keyboard, divided into a left, a center and a right section like said 6,911,970. However, top row, 1[QWE] 2[RTY] 3[UIO], requires 10 letters and [P] does not fit in and allocated to 9[M P]. At the same time, tilting the device with text-entry requires extra hand movement, and slows down text-entry speed.

Therefore, it would be desirable to provide a character input device providing standard QWERTY keyboard in three columns by four rows as 12-key keypads with quick and accurate key input of alphabets, numbers and symbols with single key press.

### BRIEF SUMMARY OF THE INVENTION

In view of the foregoing, the present invention is 12-key QWERTY text entry device and text-entry method, by utilizing none keypad area, to allocate user friendly standard QWERTY key layout in three columns by four rows, and achieve quick and accurate character entry of alphabets, numbers and symbols with single key press operation.

Merely by way of example, the key arrangement can be applied to a cellular phone product, but can also be applied to smart phone, IP phone, game consoles' controller, remote controls for home entertainment devices or computing devices, personal digital assistants (PDA), watches, karaoke controllers, car navigation controllers, single-hand use assistive PC keyboard, any combination of these, any 12 key device and the like.

In accordance with the above and other objects, the invention provides a data entry device having at least a first symbol, a second symbol and a third symbol are printed on a key-top, and a forth symbol is printed on a main case between two keypads, and at least a first switch, a second switch and a third switch are provided corresponding to the said symbols. The first switch is activated when the first symbol is pressed, the second switch is activated when the second symbol is pressed, and the said two switches are activated simultaneously when the third symbol is pressed. Right side switch of left side keypad and left side switch of right side keypad are activated when the forth symbol between two keypads pressed.

This invention also provides a method for controlling the data entry device. Signal ports of the data entry device are scanned to determine whether the state of the data entry device has changed. If yes, the position of switches being pressed is determined, and then possible outputs are determined according to the number of switches being pressed and its location.

In a specific embodiment, the invention provides a telecommunication device. The telecommunication device comprises a housing member. The telecommunication device can be a cellular phone, or other wireless devices. The telecommunication device also comprises a key board which includes a plurality of keys representative of a set of numbers including, 1,2,3,4,5,6, 7, 8, 9, 0, # and *. The keyboard is coupled to the housing member. Many or all of the said keys represent at least a first character, a second and a third character. Each of the keys comprises a first, a second, a third portion, and there is extra fourth character portion in between two keypads adjoin each other.

The telecommunication device also comprises a first switch where the first switch is activated when the first portion of the key is pressed. The telecommunication device comprises a second switch where the second switch is activated when a second portion of the key is pressed. The telecommunication device also includes a conversion device coupled to the first switch and the second switch. The conversion device has a first input coupled to the first switch and a second input coupled to the second switch. The first input is capable of transferring first output indicative of the first character and the second input is capable of transferring a second output indicative of the second character. The conversion device is also adapted to produce a third character upon receiving an input from both the first switch and the second switch when the first switch and the second switch are activated simultaneously.

The telecommunication device also includes a conversion device coupled to the second switch located on right side of left side keypad and the first switch located on left side of right side keypad. The conversion device is also adapted to produce a forth character upon receiving a simultaneous key press.

The telecommunication device also includes standard personal computer's QWERTY keypad layout such as number [1] as “QWE”, [2] as “TYU”, [3] as “OP@”, a character “R” is located between number [1] and [2] keypads, a character “I” is located between [2] and [3] keypads.

### BRIEF DESCRIPTION OF THE DRAWINGS

Embodiments of the present invention are described herein with reference to the accompanying drawings, similar reference numbers being used to indicate functionally similar elements.

FIG.-01 shows a conventional cellular phone key arrangement.

FIG.-02 shows a commercially available QWERTY keyboard for smart phone such as Blackberry.

FIG.-03 shows a commercially available two in one QWERTY keyboard with 20 keys in five columns by four rows for smart phone.

FIG.-04 shows a key of a cellular phone according to one embodiment of the present invention.

FIG.-05 shows a switch layout of a cellular phone according to one embodiment of the present invention.

FIG.-06 shows a key press position and switch location layout of a cellular phone according to one embodiment of the present invention

FIG.-07 shows a key switch circuit matrix according to one embodiment of the present invention.

FIG.-08 shows a key of a cellular phone according to one embodiment of the present invention.

FIG.-09 shows a key of a cellular phone according to another embodiment of the present invention.

FIG.-10 shows a key process sequence flowchart of a cellular phone according to the present invention.

Table.1 shows a conversion device table of a cellular phone according to the present invention which refer to FIG.-04, FIG.-08, FIG.-09 and flowchart FIG.-10

### DETAILED DESCRIPTION OF THE INVENTION

Objects and advantages of the present invention will become apparent from the following detailed description. The following description of illustrative, non-limiting embodiments of the invention discloses specific configurations and components. However, the embodiments are merely examples of the present invention, and thus the specific features described below are merely used to describe such embodiments to provide an overall understanding of the present invention. One skilled in the art readily recognizes that the present invention is not limited to the specific embodiments described below. Furthermore, certain descriptions of various configurations and components of the present invention that are known to one skilled in the art are omitted for the sake of clarity and brevity.

FIG.-04 shows 12 keys in three columns by four rows of a cellular phone according to one embodiment of the present invention.

“Q”, “W”, “E” are silk printed on a number “1” key-top of a key.
“T”, “Y”, “U” are silk printed on a number “2” key-top of a key.
“O”, “P”, “@” are silk printed on a number “3” key-top of a key.
“A”, “S”, “D” are silk printed on a number “4” key-top of a key.
“G”, “H”, “J” are silk printed on a number “5” key-top of a key.
“L”, “;”, “'” are silk printed on a number “6” key-top of a key.
“Z”, “X”, “C” are silk printed on a number “7” key-top of a key.
“B”, “N”, “M” are silk printed on a number “8” key-top of a key.
“.”, “/”, “?” are silk printed on a number “9” key-top of a key.
“SHIFT” are silk printed on a symbol “*” key-top of a key.
“SPACE” are silk printed on a symbol “0” key-top of a key.
“ENTER” are silk printed on a symbol “#” key-top of a key.
Uniqueness of this invention is additional letters are silk printed on a surface of main body.
“R” is silk printed between a number “1” and “2” area on a main panel of the devise.
“I” is silk printed between a number “2” and “3” area on a main panel of the devise.
“F” is silk printed between a number “4” and “5” area on a main panel of the devise.
“K” is silk printed between a number “5” and “6” area on a main panel of the devise.
“V” is silk printed between a number “7” and “8” area on a main panel of the devise.
“,” is silk printed between a number “8” and “9” area on a main panel of the devise.

FIG.-05 shows 1st row of QWERTY key layout according to one embodiment of the present invention. 501 is top view of 1^{st} row, 502 is a side view of keypad, 503 is a side view of surface of main body of the device, 504 are side view of switches to connect or disconnect outer ring and inner ring of 506, 505 is a side view of circuit board surface, and 506 are top view of actual circuit pattern where 504 contacts.

FIG.-06 shows a relationship between key press area and switch position of FIG.-05.

Sw-1 is located left side beneath of keypad 601, and sw-2 is located right side beneath of the same 601 keypad.
Sw-3 is located left side beneath of keypad 602, and sw-4 is located right side beneath of the same 602 keypad.
Sw-5 is located left side beneath of keypad 603, and sw-6 is located right side beneath of the same 603 keypad.

By pressing the PT01 area of key-top 601, only the sw-1 become activated, by pressing the PT02 area of key-top 601, both sw-1 and sw-2 become activated, by pressing the PT03 area of key-top 601, only the sw-2 become activated, by pressing the PT04 area between key-top 601 & key-top 602, both sw-2 and sw-3 become activated.

By pressing the PT05 area of key-top 602, only the sw-3 become activated, by pressing the PT06 area of key-top 602, both sw-3 and sw-4 become activated, by pressing the PT07 area of key-top 602, only the sw-4 become activated, by pressing the PT08 area between key-top 602 & key-top 603, both sw-4 and sw-5 become activated.
By pressing the PT09 area of key-top 603, only the sw-5 become activated, by pressing the PT10 area of key-top 603, both sw-5 and sw-6 become activated, by pressing the PT11 area of key-top 603, only the sw-6 become activated.

Uniqueness of this invention is none keypad space is also efficiently assigned additional unique character. By pressing the gap area between two keypads as shown in PT04 and PT08 area in FIG.-06, new character such as “R” or “I” are assigned.

FIG.-07 shows key can matrix according to one embodiment of the present invention. 701 is a controller to send key scan output signal from 708˜711 to said key scan matrix circuit and scan the key press status and capture status as key scan input signals 702˜707 back to controller 701˜712 shows a concept of switch, and 702˜707 are connected to key input ports of controller 701 and pulled up “High” through resister 708˜711 are connected to key scan output signal ports of controller 701 and kept “high” except key scanning timing of the specific line. For example, when output the scan signal 708 as “Low”, and 709˜711 keep “High”, sw-1˜sw-6 switch on/off status reflect the 1^{st} row key press status through 702˜707 and captured by controller 701. When some part of key-top is pressed, associated switch or switches are activated. If one of switches pressed, corresponding input port becomes “low” at the specific scanning timing of 708˜711. For example, when PT01 position of number 1(QWE) key pressed, 702 input becomes “Low” and 703˜707 are kept “High” at the timing of 708 scanning signal becomes “Low”. Controller 701 keep scanning all switches' on/off status continually, and perform further data conversion to display appropriate character.

FIG.-08 shows 12 keys in three columns by four rows of a cellular phone according to another embodiment of the present invention. By comparison with FIG.-04, additional set of silk are printed for each keypad and main surface area in between two keypads.

Table.1 shows a conversion table how the key press position converted into output characters. The “ON” status show that the applicable keypad position (PT01˜PT11) is pressed and switches are activated. The “OFF” status show that the applicable keypad position (PT01˜PT11) is not pressed and switches are NOT activated.

FIG.-10 shows a brief key process sequence flow chart of said FIG.-07 key scan and said Table.1 data conversion according to one embodiment of the present application. Key process sequence start at 901 by performing key scan all key switch status at said FIG.-07 explanation, and saves all 702˜707 status for each row (1^{st}˜4th) data into internal memory of controller. Then, compare the value with formerly scanned data at 902 after removing key chattering or electronics noise. If there is no key data change, it ends its key process. If there is any key data change at 902, identify the row of the changes at 903.

As shown in table.1, if any of sw-1˜sw6 of 4 rows are “ON” position at 904, then identify its specific position PT01˜PT11 at 905, allocate appropriate character output by referring conversion table.1 at 906, then display applicable character at 907. Said displayed character is tentative until the key status become “key off” at 904. By releasing a finger completely from the key pressed position, the displayed character become fixed entry at 909, and move a cursor pointer to next character entry position on the display device.

As shown in FIG.-08, special functions are assigned to 4^{th} row keypads, SHIFT, SPACE and ENTER keys according to one embodiment of the present invention.

The “*” key is assigned as “SHIFT” key for PT01˜PT03. The number “0” key is assigned as “SPACE” key for PT05˜PT07”. The “#” key is assigned as “ENTER” key for PT09˜PT11.

As shown in FIG.-08, there arc special character sets silk printed on upper half of each key-top and main surface body by comparing FIG.-04. These extra character sets are numbers and symbols similar as standard PC keyboard. SHIFT (*) key has special operation to change next letter entry mode.

By pressing left side of SHIFT key at PT01 area where “SYM” icon displayed, then only the following next key entry becomes symbol and number entry mode. “SYM” silk color may coordinate with same color with upper character sets of all keys and main surface body.

By pressing right side of SHIFT key at PT03, then only the following first key entry becomes upper case alphabet entry mode. “Aa” mark color may coordinate with same color with lower character sets of all key and main surface body.

By pressing the middle of SHIFT key at PT02, “*” is selected. SHIFT key operate similar manner like standard PC keyboard, and maximizes total character entry in double, and covers almost all standard QWERTY keyboard key entries.

Said “SPACE” (0) key may functions slightly different manner after SHIFT key press. Under this special condition, by pressing left side of keypad “0” at PT05, CAPS is locked. CAPS lock status should be reflected in some part of display area or by LED. After this operation, Upper case becomes original alphabet mode instead of lower case mode. To unlock the CAPS lock condition, it is required to do the same operation. Press any part of “SHIFT” (*) key, then pressing left side of keypad “0” at PT05. The CAPS lock status become inactive.

By pressing right side of “SPACE” (0) key at PT07 after SHIFT key press, then NUM lock is set. NUM lock status should be reflected in some part of display area or by LED. After this operation, key press of any part of 10 keys operates as number entry. To cancel NUM lock status, it is required to repeat the same operation.

Said CAPS LOCK and NUM LOCK functions are optional.

Said “ENTER” (#) key functions slightly different manner after SHIFT key press. Under this special condition, by pressing left side of keypad “#” at PT09, then generates Ctrl+ key code, and by pressing right side of keypad “#” at PT11, then generates Alt+ key code.

As shown in FIG.-08, f1, f2, f3, and f4 also work as different functionality by pressing PT04 or PT08 position of 4^{th} row. User may define as specific application to launch, or pre-define as either “Back space”, “Delete”, “Home”, “END”, “PGUP”, “PGDN”, “INS”, “ESC”, “TAB+”, “TAB−”, etc.

Normally, “CLR”, same as “Back Space”, function is available as independent key for standard cellular phone, so “CLR” function is not described in this invention. However, “Backspace” and “DEL” might be desirable to assign the said f1-f4 area.

### DETAILED DESCRIPTION OF ANOTHER EMBODIMENT OF THE INVENTION

FIG.-09 shows full keyboard by featuring standard [2abc] cellular phone key assignment according to another embodiment of the present invention. Table.1 can be assigned completely different key conversion table easily by changing assigned output. The benefit for this invention achieves single press character entry for existing [2abc] style keypad as shown in FIG.-01. Since basic number and alphabet allocation are same as standard [2abc] style, user can also switch input method between standard multiple key press mode and single key press mode of this invention.

For example at 3^{rd} row, user simply press left side of number [7] keypad at PT01 for “P”, press middle of number [7]keypad at PT02 for “Q”, press right side of number [7] keypad at PT03 for “R”, and main surface area between number [7]&[8] at PT04 for “S”. Furthermore, “T” for left side of number [8] keypad at PT05, “U” for middle of number [8] keypad at PT06, “V” for right side of number [8] keypad at PT07, “W” for main surface area between number [8]&[9] at PT08, “X” for left side of number [9] keypad at PT09, “Y” for middle of number [8] keypad at PT10, and “Z” for right side of number 191 keypad at PT11.

FIG.-09's symbol allocation is slightly different from FIG.-08. For example, to select apostrophe +S “'s”, simply press right side of SHIFT key, then “S” silk area between number [7]&[8] to select apostrophe, and press the same position to select “S”. Symbols allocations are carefully decided to minimize the extra effort in actual text entry.

Another embodiment of this invention may combine extra key on the device to select simultaneous SHIFT key operation. User type alphabets with SHIFT key press to change tentative case sensitivity on PC keyboard. By adopting extra keypad on its side of cellular phone, or utilizing existing volume key or other available key, user can type alphabet by thumb, and push SHIFT key by other finger simultaneously to change tentative case sensitivity.

Another embodiment of this invention changes the shape of keypad to distinguish left, middle, right, or middle of two keypads. User can minimize wrong key entry by adding a different urde in the middle of keypad.

Another embodiment of this invention changes the keystroke depth, diameter of switches, necessary force to press, or clicking feeling. User can minimize wrong key entry by adding a different feeling to switches. By changing the shape or height of convex beneath keypad also adds different feedback to user.

Another embodiment of this invention changes the clicking effect sound by the location of switches. User can minimize wrong key entry by getting sound feedback before releasing a key.

Another embodiment of this invention unifies same row switches as a connected single part to minimize the defect rate and cost of switches. As shown in FIG.-07, outer rings of each row switches are electronically connected. Making dome switches sw-1˜sw-6 as unified part where the outer edges are connected each other through narrow metal plate, defect rate and cost becomes lower by a single press manufacturing process.

Another embodiment of this invention utilize main surface area between different row. As shown in FIG.-07, key scan process can also retrieves simultaneous key press between different rows. For example, by pressing middle of “Q” and “A”, PT01 position of both 1^{st} row and 2^{nd} row are ON. 33 additional silk can be printed on FIG.-08 or FIG.-09. Pictograph, hieroglyphic, emoticon, or any other functions can be assignable.

Another embodiment of this invention expands usability of games or other applications. For example, user can shoot down the flying objects by changing the angle of cannon while moving left or right. When number [4] is assigned to move “LEFT”, user can also change the angle of cannon to anticlockwise direction by pressing PT01 to rotate cannon, and rotate to clockwise by pressing PT03, and stop the rotation by pressing PT02 while keep moving its chassis to “LEFT”.

Another embodiment of this invention is combined with word prediction technology. As shown in FIG. 03. There is a technology to select single letter from multiple candidates. However, there is a limitation for existing predictive solution and required to change the input method between multiple key press mode, and slow down input process. By adding this invention, predicted words will be displayed in a proper order, and also eliminate a risk for user to switch to multiple key press entry. User can enjoy a selection of predicted words, and can minimize wrong key entry by mistake.

Although the invention is described above with reference to a key arrangement of a cellular phone, the invention can be used in other electrical devices, such as smart phones, IP phones, cordless phones, combination telephone recorders, fax machines, PDAs, watches, remote controllers, game controllers, Karaoke controllers, car navigation controllers, and even as a single-hand use assistive PC keyboard.

Remote controllers can be of a type used to control any type of electronic device, including audio and video equipment, PCs including presentation controller, VOD (Video on Demand), Cable TV receiver, TIVO devices, or game consoles. There can also be other alternatives that would be recognized by one of ordinary skill in the art.

The previous description of embodiments is provided to enable a person skilled in the art to make and use the present invention. Moreover, various modifications to these embodiments will be readily apparent to those skilled in the art, and the generic principles and specific examples defied herein may be applied to other embodiments without the use of inventive faculty. For example, some or all of the features of the different embodiments discussed above may be deleted from the embodiment. Therefore, the present invention is not intended to be limited to the embodiments described herein but is to be accorded the widest scope defined only by the claims below and equivalents thereof.

What is claimed is:

1. 12-key QWERTY text entry device and text-entry method comprising:
12 keys in three columns by four rows;
each key consist of three unique symbols on its surface;
each gap area between two neighboring keys with one unique symbol on its surface of the main body;
each key with first part of key-top with a first symbol on its surface;
a first switch, activated when said first part of the key-top is pressed;
each key with a second part of key-top with a second symbol on its surface;
a second switch, activated when said second part of the key-top is pressed;
each key with a conversion means having inputs coupled to first and second switches,
said conversion means producing an output having states unique to respective combinations of activation states of said first and second switches; said conversion means producing an output having states unique to respective combinations of activation states of said second switch of said each key and first switch of its neighboring key including simultaneous activation, achieves 11 unique states to support 11 unique symbols in each row.

2. 12-key QWERTY text entry device of claim 1, further comprising:
“QWE” symbols are assigned to number “1” key-top;
“R” symbol is assigned to main body surface in between number 1 and number 2 key;
“TYU” symbols are assigned to number “2” key-top;
“I” symbol is assigned to main body surface in between number 2 and number 3 key;
“OP@” symbols are assigned to number “3” key-top; said
11 unique states per row achieve standard QWERTY key layout with a single key press operation to type each alphabet.

3. 12-key QWERTY text entry device of claim 2, further comprising:
“SHIFT” function is assigned to symbol “*” key-top;
“SPACE” function is assigned to number “0” key-top;
“ENTER” function is assigned to symbol “#” key-top; said
any part of “0” key press operates as SPACE function, and any part of “#” key press operate as ENTER (carriage return) function even though SHIFT key works in a different manner. Said first switch activation of said “SHIFT” (*) key changes case sensitivity of the following single key text entry operation.

4. 12-key QWERTY text entry device of claim 3, further comprising:
each key consist of additional three unique symbols on its key-top and total up to six unique symbols are assignable for each keypad;
each gap area between two neighboring keys with additional one unique symbol on its surface of the main body and total 2 unique symbols are assignable for each key gap;
said second switch activation of said “SHIFT” key changes text entry mode from alphabet entry mode to number and symbol data entry mode, and enable said 12-key QWERTY text entry device as efficient as standard QWERTY keyboard

5. 12-key QWERTY text entry device of claim 1, further comprising:
each gap area between two neighboring keys between different rows with additional unique symbols on its surface of the main body; said conversion means producing an output having states unique to respective combinations of activation states of said first switch of said key and first switch of its neighboring key in different row including simultaneous activation, achieves additional unique states to support additional symbols or application shortcuts.

6. 12-key QWERTY text entry device of claim 1, further comprising: additional third switch for each key for square or round shape key-top devices, said third switch replace said conversion means to produce said unique states, and combinations of activation states of said first, second, and third switches expand additional function.

7. 12-key QWERTY text entry device of claim 1, wherein the key-top shape is unique to feedback differences between said first part of key-top, said second part of key-top, middle of key-top, and middle of neighboring key-tops.

8. 12-key QWERTY text entry device of claim 1, wherein the effect sound of key press are different between said first part of key-top, said second part of key-top, middle of key-top, and middle of neighboring key-tops.

9. 12-key QWERTY text entry device of claim 1, further comprising:
a display device to feedback the selected symbol with neighboring symbols, and highlight the said selected symbol to notify user the key pressed position before finalize the input.

10. 12-key QWERTY text entry device of claim 1, further comprising:
a first LED and a second LED; said
a first LED turns ON when said first switch is on when said first part of key-top is pressed; a second LED turns ON when said second switch is on when said second part of key-top is pressed;
said both first and second LEDs turns ON when said first and second switches are on simultaneously when pressed middle of said first and second part of key-top; said both first and second LEDs turns OFF when said second switch is on and first switch of its neighboring key is on by pressing said gap area between two neighboring keys, and notify user the key press position.

11. 12-key QWERTY text entry device of claim 1, wherein the depth of keystroke are different between said first part of key-top and said second part of key-top.

12. 12-key QWERTY text entry device of claim 1, wherein at least one of the switches a dome switch.

13. 12-key QWERTY text entry device of claim 11, further comprising six dome switches on a same raw are made as unified single part where the outer edges are connected each other through narrow metal plate to decrease cost and lower defect rate in the process of manufacturing.

14. 12-key QWERTY text entry device of claim 1, further comprising at least two conductive pills at the bottom of the key-top, the first conductive pill corresponding to the first part of the key-top and the second conductive pill corresponding to the second part of the key-top to decrease cost.

15. 12-key QWERTY text entry device of claim 14, further comprising a circuit board having at least two conductors, wherein the first conductor contacts the first conductive pill when the first part of the key-top is pressed, and the second conductor contacts the second conductive pill when the second part of the key-top is pressed.

16. 12-key QWERTY text entry device of claim 1, wherein said conversion means comprises software means and memory device having a conversion table stored therein for converting activation states.

17. (canceled)

18. 12-key text entry device of claim 1˜17, wherein said symbol assignment for each number key is based on standard [2abc] phone key assignment;
“PQR” symbols are assigned to number “7” key-top;
“S” symbol is assigned to main body surface in between number 7 and number 8 key;
“TUV” symbols are assigned to number “8” key-top;
“W” symbol is assigned to main body surface in between number 8 and number 9 key;
“XYZ” symbols are assigned to number “9” key-top; said
11 unique states per row achieve single click operation to select each symbol instead of multiple key press key entry.

19. Text entry device of claim 1˜18, wherein said text entry device is either a cellular phone, smart phones, IP phones, cordless phones, combination telephone recorders, fax machines, PDAs, watches, remote controllers, game controllers, Karaoke controllers, car 4. navigation controllers, or single-hand use assistive PC keyboard.

20. A computer program product containing program code for performing the method according to claim 19.
